(19) United States
(12) Patent Application Publication
(10) Pub. No.: US 2017/0197887 A1
(43) Pub. Date: Jul. 13, 2017

(54) METHOD OF ANNEALING CERAMIC GLASS BY LASER

(71) Applicants: Ratnakar D. Vispute, Columbia, MD (US); Ashok Chaudhari, Briarcliff Manor, NY (US)

(72) Inventors: Ratnakar D. Vispute, Columbia, MD (US); Ashok Chaudhari, Briarcliff Manor, NY (US)

(73) Assignees: Blue Wave Semiconductors, Inc., Baltimore, MD (US); Solar-Tectic, LLC, Briarcliff Manor, NY (US)

(21) Appl. No.: 15/470,161

(22) Filed: Mar. 27, 2017

Related U.S. Application Data
(63) Continuation-in-part of application No. 14/663,067, filed on Mar. 19, 2015.
(60) Provisional application No. 61/955,543, filed on Mar. 19, 2014.
(60) Provisional application No. 62/382,817, filed on Sep. 2, 2016.

(51) Int. Cl. C04B 37/04; C03C 17/22

(52) U.S. Cl. CPC C04B 37/045; C03C 17/22; H01L 51/0096

(57) ABSTRACT

A method for annealing thin-films of ceramics such as Al₂O₃ on glass by laser such that the underlying glass substrate is unaffected by the laser heating. This is accomplished by applying a thin MgO buffer layer to the glass, depositing an amorphous ceramic layer on the textured transparent buffer layer, and annealing the ceramic layer with a heated line source. The ceramic layer crystallizing forming a ceramic coated substrate. The buffer layer is also textured which serves to induce texture in the Al₂O₃ film deposited on the buffer layer. The induced texture on the Al₂O₃ provides advantageous properties. The ceramic glass can be used for a variety of applications such as covers to solar panels, CICs used in satellites, displays, automobile windows, and substrates for LEDs.

### PRIORITY AND RELATED APPLICATION

This application is a Continuation in Part of U.S. patent application Ser. No. 14/663,067, filed Mar. 19, 2015, entitled “Method of Making Ceramic Glass,” which claims priority to U.S. Provisional Patent Application Ser. No. 61/955,543, filed Mar. 19, 2014, entitled “Method of Making Sapphire Glass.” The present application also claims priority to U.S. Provisional Application 62/382,817, filed Sep. 2, 2016, entitled “Sapphire Glass Annealing Process.” All three applications are hereby incorporated by reference their entirety.

### FIELD OF THE INVENTION

The present invention relates to covers for displays used in devices such as smartphones, smartwatches, and computers, and to substrates used in various electronic devices such as thin-film photovoltaic modules, Light Emitting Diodes (LEDs), and Field Effect Transistors (FETs).

### BACKGROUND OF THE INVENTION

Sapphire or “sapphire glass,” as it is sometimes called, is a ceramic that has many industrial applications, from watch covers to envelopes for use in high temperature lamps. It is also used in military applications. Covers used in many electronic devices today, such as displays, require not only transparency but hardness for anti-scratch capability. Sapphire, one of the hardest materials, is an ideal material to meet this need. Recently, sapphire or single crystalline Al₂O₃ has been referred to as “sapphire glass” which is a layman's term meant to highlight the fact that crystalline Al₂O₃ is transparent like glass. As a transparent material with a hardness only second to diamond, it has been claimed recently as an ideal material for display covers. But sapphire glass has in fact long been used in the semiconductor industry for various applications, along with other industries such as the watch industry, for just one example. The one and only drawback of sapphire, at least as far as scratch-resistance goes, has been cost. Recently there have been attempts to reduce the price of sapphire glass for use as display covers by GTAT and Apple Inc., that disclosed methods for making inexpensive sapphire glass. Apple has disclosed additional technology for sapphire glass covers in patent applications, as have other companies, such as Corning Inc. “Sapphire glass” should therefore be considered to include polycrystalline or nanocrystalline Al₂O₃ (not just single crystalline) given recent patent disclosures by Apple Inc.

Industrial sapphire is created by melting aluminum oxide (Al₂O₃) at 2040° C. and then encouraging crystal growth with a seed and careful control of the environment. Manufacturers have developed several unique methods for growth, with varying levels of resultant quality, size, and cost. The EFG or Stephanov methods allow the directed growth of shapes like ribbon, or even tubes, however there are many limitations to what can be done. The Czochralski, HEM, or Kiropolous methods allow the highest optical quality sapphire, but the result is a rod-like “blob” of crystal called a boule, that must be entirely machined into useable shapes and sizes. Traditionally sapphire glass has been manufactured by forming boules by either the Verneuil or Czochralski processes and then slicing the sapphire from these boules. However, this method requires very high temperatures and cutting and polishing the sapphire boules requires added time and process challenges. More to the point, when making sapphire glass for devices such as smartphones, or other small devices, sapphire ingot yield rates can be as low as below 50 percent. For these and other reasons, sapphire glass as it is currently produced is expensive and not economical. Alternatively, one can make sapphire glass by sintering Al₂O₃ powder in order to form small grain Al₂O₃ material. Crystalline Al₂O₃ made from small grains is known to be as hard and potentially even harder than single crystal sapphire or sapphire glass. However, this sintering process must also be performed at very high temperature, greater than 1200° C., and the process is also quite involved and so far has not been a commercially viable solution to making inexpensive sapphire glass. Recently, an invention for improving sapphire glass manufacturing was disclosed by Chaudhari et al (see US 2014/0116329) and “Extremely highly textured MgO crystalline films on soda-lime glass by e-beam” (Materials Letters 121 (2014) 47-49). These disclosures fail, however, to provide a method for making an enhanced quality ceramic (e.g. sapphire) layer on the crystalline MgO substrate.

Thus, a new method is disclosed here that will not only provide sapphire glass that is cost effective, simple, can take place at low temperatures (ideally 600 C or below), and also provide small grains for added hard, scratch-free, material, but can provide an enhanced, high quality ceramic layer such as sapphire. In accordance with one aspect of the present invention, the foregoing and other objects can be achieved by using the common electron beam (e-beam) evaporation process known in the trade, and depositing Magnesium Oxide (MgO) on a soda-lime glass substrate.

In accordance with another aspect of the present invention the foregoing and other objects can be achieved by using e-beam evaporating Al in an O₂ atmosphere to get a crystalline film on the MgO layer previously deposited. Specifically, this is done by evaporating Al and then adding O₂ so that Al reacts with O₂ on the surface of the MgO to form crystalline oxide.

In accordance with another aspect of the present invention the foregoing and other objects can be achieved by keeping Al on the MgO surface so it can spread on the surface to form a desired crystalline phase.

### BRIEF SUMMARY OF THE INVENTION

Ceramic glass, such as sapphire glass, is produced using e-beam to deposit Magnesium Oxide on a soda-lime glass substrate, followed by evaporation of Al in an O₂ atmosphere to get a crystalline film on the previously deposited MgO layer.

### BRIEF DESCRIPTION OF THE DRAWING

FIG. 1 shows TEM cross section of Al₂O₃ on highly textured MgO [111] layer. The MgO layer is on soda-lime glass, which cannot be seen here. Additionally, the Al₂O₃ film here is entirely amorphous (and therefore not the aim of the disclosed invention but demonstrates a step in that direction).

FIG. 2 is TEM diffraction pattern of highly textured MgO [111] film on soda-lime glass showing highly aligned, and textured, MgO.

### DETAILED DESCRIPTION OF THE INVENTION

Transparent ceramics have many useful applications and consist of a number of materials. Sapphire (Al₂O₃), Spinel (MgAl₂O₄), AlON (Aluminium oxynitride spinel (Al₂₃O₂₇N₅)), and ZrO₂ are some of the most common and there are others. Today transparent ceramics are commonly made transparent by sintering. Here a novel method for making transparent ceramics from these materials is presented which replaces sintering with a process that has many advantages such as lower temperature, high texture, less material, simpler deposition, and potential for scalability.

In one embodiment of the invention, a thin layer of metal is deposited on a crystalline Magnesium Oxide (MgO) coated glass substrate followed by the introduction of oxygen (O₂). For example, in one embodiment, Al (aluminum) is deposited as a thin layer on the crystalline coated glass substrate followed by the introduction of O₂. The crystalline MgO coated substrate can be fabricated using the process disclosed by A. Chaudhari et al in “Extremely highly textured MgO[111] crystalline films on soda-lime glass by e-beam” and in US patent application 2014/0245947 by Vispute and Seiser. Alternatively, the crystalline MgO can be deposited by any of the other techniques known in the art, such as Inclined Substrate Deposition (ISD) or Ion Beam Assisted Deposition (MAD).

It should be noted that having two layers of material, for example Al₂O₃ and MgO, that are different, may have beneficial qualities. For example, the Al₂O₃ may be less likely to crack since the underlying layer is a different material and perhaps has a different orientation. This “weaving” effect may serve to strengthen the final cover material or film and have other beneficial effects.

The Al is deposited on the MgO/glass substrate at 550° C. and when O₂ is introduced a crystalline Al₂O₃ is formed. The Al is deposited 1 nm at a time, combined with O₂. If a thicker Al film were deposited, for example 500 nm, combined with O₂, then an Al₂O₃ film would form on the Al and it would be impossible to grow the crystalline Al₂O₃. The number of lnm Al with O₂ layers can vary according to the desired outcome. For example, a thicker layer may give better hardness value (Hv) as measured by Vickers or Knoop. On the other hand, a thinner layer may provide better transparency or real in-line transmission. Although small grains are preferable for increased hardness, according to the Hall-Petch relationship, it may be desirable in certain instances to increase the grain size. For example, larger grains are beneficial when depositing semiconductor thin-films such as silicon for solar cells, or GaN for LEDs. In this case, annealing the substrate after deposition of the Al₂O₃ layer may increase crystallinity and grain size.

It is known that Al₂O₃ has different phases, such as gamma and alpha. Moreover, it is known that each phase has certain attributes that can be desirable depending on the need. There are advantages and disadvantages to using alpha and gamma phases. In this invention, two different phases of Al₂O₃ are disclosed, alpha and gamma. For applications such as cover glass, hardness (Hv) is crucial for anti-scratch capability. In such applications, the sapphire (crystalline Al₂O₃ layer) may have a crystal structure that is gamma, since gamma phase Al₂O₃ is cubic. Moreover, another benefit of the cubic, gamma phase is that the non-cubic, alpha phase of Al₂O₃ has birefringence which reduces transparency. As it so happens, since the Al₂O₃ layer is deposited below 700° C. it is likely that the Al₂O₃ is cubic, because the phase of the Al₂O₃ is most likely gamma. With regard to alpha phase Al₂O₃, it is known that birefringence along the optic of c-axis of the alpha Al₂O₃ is eliminated. For alpha Al₂O₃ the c-axis is [006]. Finally anisotropic single crystal materials exhibit some properties such as thermal expansion and hardness which vary significantly by orientation. For example, sapphire with crystal orientation perpendicular to the c-axis is harder than orientation parallel to the c-axis. And c-axis sapphire is harder than other axes in Al₂O₃, such as r, n, or a.

Thus in one embodiment there is deposition of a gamma phase of Al₂O₃ and in another embodiment an alpha phase of Al₂O₃, and both embodiments are deposited heteroepitaxially on a crystalline MgO buffer layer on soda-lime glass. Each phase of Al₂O₃ is deposited separately, and can be chosen depending on the desired outcome.

Upon completion of the deposition process, polishing may or may not be required depending on the use. If the sapphire glass is going to be used for display covers, for example, it is unlikely that it needs polishing which would be an additional cost-savings advantage over current sapphire manufacturing techniques. If the sapphire glass is going to be used as a substrate for additional device fabrication on which layers will be deposited, then some polishing may be beneficial. If the sapphire glass is, for example, polycrystalline then crystallographic orientations being exposed on the surface potentially make a polishing operation difficult to achieve a quality surface as the different crystal planes of sapphire polish at different rates. If the sapphire glass is highly textured, and the crystal orientations have more or less the same planes, then polishing may be easier. In this case more time and money would be saved.

Finally, highly textured ceramic layers as discussed here, can serve as substrates on which to deposit highly textured heteroepitaxial semiconductor films such as silicon which due to the aligned grains can have advantageous light trapping and reflection control helpful in the case of solar cell devices (see Campbell et al, “Light trapping and reflection control in solar cells using tilted crystallographic surface textures,” 1993). The textured ceramics discussed here may have the same or similar light trapping and reflection properties.

### EXAMPLE 1

E-beam evaporation technique was used for the growth of sapphire glass. The evaporator consists of a stainless steel high vacuum chamber capable of reaching 10 E-7 Torr with the help of a cryopump. Initial rough vacuum up to 10-3 Torr was achieved with a mechanical dry pump. Prior to vacuuming the chamber, batches of initial glass substrates were loaded on a substrate heater that is capable of controlling temperature of the substrates while growing the MgO buffer layer and sapphire layer in reactive deposition mode. A typical buffer layer of MgO was grown from stoichiometric MgO source material. The presence of background pressure of O₂ (˜10 E-4 Torr using O₂ flow need valve)) helps high quality stoichiometric MgO depositions. Substrate temperature was controlled from 300C to 650 C temperature range to control the preferred orientation of the MgO films. Required growth temperature was set using a substrate heater with a typical ramp rate ranging from 15 C/min to 45 C/min. At this stage the system is ready for deposition of the first layer that is MgO. E-beam parameters such as high voltage and emission current were set so that the appropriate evaporation rate of MgO can be achieved. The high voltage (HV approximately 8 KV) for electron beam was setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition was conducted for 1 to 2 hrs depending upon the film thickness requirement. Studies show varied film thickness of MgO films from a few microns to 6 microns is possible. After MgO deposition, a high purity aluminum (99.999) source was switched for deposition. Initially, the Al source was heated by ebeam to melt the source and the ebeam was adjusted for evaporation of aluminum. Partial pressure was adjusted from 10-4 Torr to 10-6 Torr in order to control reaction of the Al with O₂ on the substrate. Note that the arrival rate of O₂ is adjusted in a way that Al surface mobility can be as high as possible to allow surface migration and then reaction with oxygen so that crystalline properties, grain size, surface smoothness, optical transparency, and interface reaction can be controlled. Thus optimization of aluminum oxide (Al₂O₃) growth includes arrival rates of oxygen background reactive gas atoms and ebeam evaporated aluminum in such a way that aluminum has optimum surface migration for crystallinity and grain size control and reaction with oxygen to form crystalline sapphire (Al₂O₃) or sapphire glass.

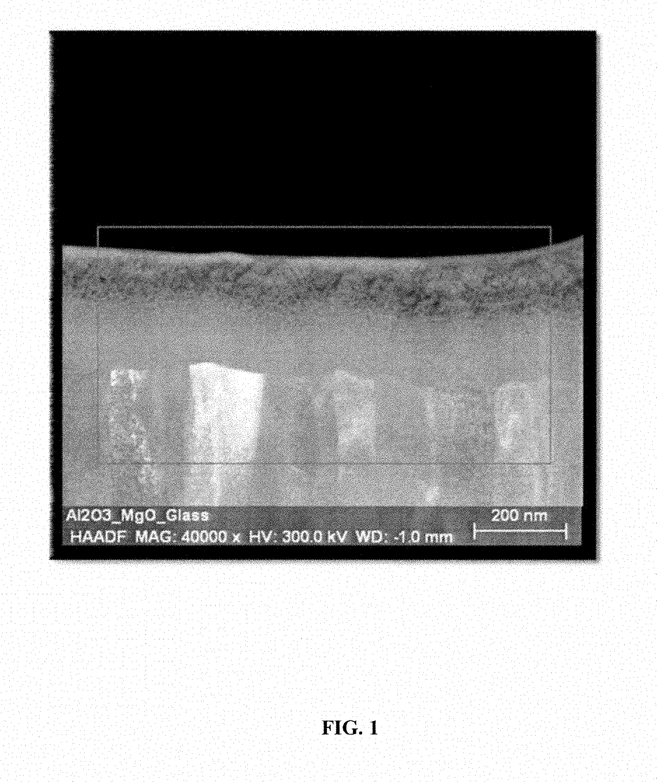

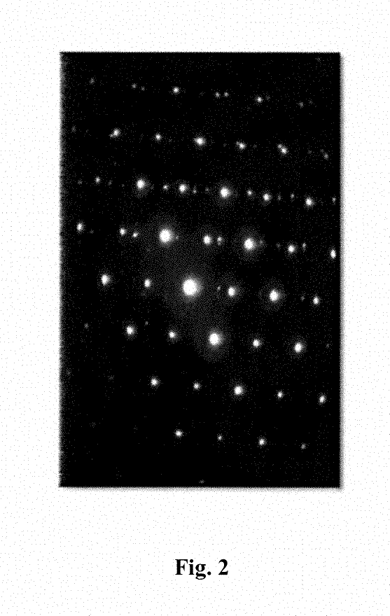

FIG. 1 shows TEM cross section of Al₂O₃ on highly textured MgO [111] layer. The MgO layer is on soda-lime glass, which cannot be seen here. Additionally, the Al₂O₃ film here is entirely amorphous (and therefore not the result of the inventive process, but is a step toward proof in conception). FIG. 2 shows TEM diffraction pattern of highly textured MgO [111] film on soda-lime glass showing highly aligned, and textured, MgO.

### EXAMPLE 2

The same process as in example 1 can be used to grow Zirconium Oxide (ZrO2).

E-beam evaporation technique is used for the growth of zirconium glass. The evaporator consists of a stainless steel high vacuum chamber capable of reaching 10 E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO was grown from stoichiometric MgO source material. The presence of background pressure of O₂ (˜10 E-4 Torr using O₂ flow need valve)) helps high quality stoichiometric MgO depositions. Substrate temperature was controlled from 300 C to 650 C temperature range to control the preferred orientation of the MgO films. Required growth temperature is set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam is setup through potentiometer of the ebeam evaporator system. A range for setting the bias for Telemark sources may be between 17 to 20 A. The electron beam sweep pattern settings can also be judged and finalized without affecting the material. The ebeam system also has a joystick that can directly control the e-beam output position, allowing the precondition of the material manually. Once high voltage and emission current is set with desirable evaporation rate of MgO, deposition is conducted for 1 to 2 hrs depending upon the film thickness requirement. Studies show varied film thickness of MgO films from a few microns to 6 microns is possible. After MgO deposition, high purity zirconium (99.999) source is switched for deposition. Initially, the Zr source was heated by ebeam to melt the source and the ebeam is adjusted for evaporation of zirconium. Partial pressure was adjusted from 10-4 Torr to 10-6 Torr in order to control reaction of the Zr with O₂ on the substrate. Note that the arrival rate of O₂ is adjusted in a way that Zr surface mobility can be as high as possible to allow surface migration and then reaction with oxygen so that crystalline properties, grain size, surface smoothness, optical transparency, and interface reaction can be controlled. Thus optimization of zirconium oxide (Zr O₂) growth includes arrival rates of oxygen background reactive gas atoms and ebeam evaporated aluminum in such a way that Zr has optimum surface migration for crystallinity and grain size control and reaction with oxygen to form crystalline zirconium (Zr O₂).

### EXAMPLE 3

The same process as in example 1 can be used to grow silicon oxide (Si O₂).

E-beam evaporation technique was used for the growth of silicon oxide ceramic. The evaporator consists of a stainless steel high vacuum chamber capable of reaching 10 E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO is grown from stoichiometric MgO source material. The presence of background pressure of O₂ (˜10 E-4 Torr using O₂ flow need valve)) helps high quality stoichiometric MgO depositions. Substrate temperature is controlled from 300 C to 650 C temperature range to control the preferred orientation of the MgO films. Required growth temperature was set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam is setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition was conducted for 1 to 2 hrs depending upon the film thickness requirement. Studies show varied film thickness of MgO films from a few microns to 6 microns is possible. After MgO deposition, high purity Si (99.999) source was switched for deposition. Initially, the Si source was heated by ebeam to melt the source and the ebeam is adjusted for evaporation of Si. Partial pressure was adjusted from 10-4 Torr to 10-6 Torr in order to control reaction of the Si with O₂ on the substrate. Note that the arrival rate of O₂ is adjusted in a way that Si surface mobility can be as high as possible to allow surface migration and then reaction with oxygen so that crystalline properties, grain size, surface smoothness, optical transparency, and interface reaction can be controlled. Thus optimization of Si oxide (SiO₂) growth includes arrival rates of oxygen background reactive gas atoms and ebeam evaporated silicon in such a way that silicon has optimum surface migration for crystallinity and grain size control and reaction with oxygen to form crystalline silicon oxide (SiO₂).

### EXAMPLE 4

The same process as in example 1 can be used to grow a nitride, such as titanium nitride (TiN) ceramic.

E-beam evaporation technique is used for the growth of TiN. The evaporator consists of a stainless steel high vacuum chamber capable of reaching 10 E-7 Torr with the help of a cryopump. Initial rough vacuum up to 10-3 Torr is achieved with a mechanical dry pump. Prior to vacuuming the chamber, batches of initial glass substrates are loaded on a substrate heater that is capable of controlling temperature of the substrates while growing the MgO buffer layer and sapphire layer in reactive deposition mode. A typical buffer layer of MgO is grown from stoichiometric MgO source material. The presence of background pressure of O₂ (˜10 E-4 Torr using O₂ flow need valve)) helps high quality stoichiometric MgO depositions. Substrate temperature is controlled from 300 C to 650 C temperature range to control the preferred orientation of the MgO films. Required growth temperature is set using a substrate heater with a typical ramp rate ranging from 15 C/min to 45 C/min. At this state the system is ready for deposition of the first layer that is MgO. E-beam parameters such as high voltage and emission current are set so that the appropriate evaporation rate of MgO can be achieved. The high voltage (HV approximately 8 KV) for electron beam was setup through potentiometer of the ebeam evaporator system. A good range for setting the bias for Telemark sources is between 17 to 20 A. The electron beam sweep pattern settings can also be judged and finalized without affecting the material. The ebeam system also has joystick that can directly control the e-beam output position, allowing the precondition of the material manually. Once high voltage and emission current is set with desirable evaporation rate of MgO, deposition is conducted for 1 to 2 hrs depending upon the film thickness requirement. Studies show varied film thickness of MgO films from a few microns to 6 microns is possible. After MgO deposition, high purity titanium (99.999) source is switched for deposition. Initially, the Ti source is heated by ebeam to melt the source and the ebeam is adjusted for evaporation of titanium. Partial pressure is adjusted from 10-4 Torr to 10-6 Torr in order to control reaction of the Ti with O₂ on the substrate. Note that the arrival rate of O₂ is adjusted in a way that Ti surface mobility can be as high as possible to allow surface migration and then reaction with oxygen so that crystalline properties, grain size, surface smoothness, optical transparency, and interface reaction can be controlled. Thus optimization of Ti nitride (TiN) growth includes arrival rates of oxygen background reactive gas atoms and ebeam evaporated Ti in such a way that Ti has optimum surface migration for crystallinity and grain size control and reaction with oxygen to form crystalline titanium nitride (TiN).

In the preceding samples further annealing, for example for 1 or 2 hours, with Ar, or O₂, may be desirable.

When designing glass for cover purposes, reflectivity is an issue that needs to be addressed. The greater the reflectivity the lower the transmission. Therefore, it can be advantageous to add an anti-reflection coating to the Al₂O₃, or ceramic, layer.

Ceramic coatings such as sapphire can provide a hard protective layer when applied to softer materials such as glass. This may be desirable when making displays or car windows, or covers for solar panels which may require anti-scratch protection from sand or other sharp abrasives. One way of making “sapphire glass” is to deposit amorphous Al₂O₃ on glass and then anneal using a laser or other heated line source, such as e-beam for example. A laser process has for example been disclosed by Apple Inc. in patent application US 2016/0248051. Simply, this process involves using a carbon dioxide laser having a wavelength that is absorbed in the Al₂O₃ coating without being absorbed by the glass substrate so the glass substrate is not damaged (i.e. without thermal impact of the glass) during the laser annealing process. The carbon dioxide laser is not applicable in the present invention. However, it would be even more helpful if there were a way to anneal the Al₂O₃ without damaging (e.g. without thermal impact) the glass that would allow for a variety of different kinds of lasers using different wavelengths of light.

An embodiment of the present invention allows for annealing of Al₂O₃ on glass or any other transparent substrate (e.g. plastic, transparent ceramic substrates) by providing a transparent buffer layer between the glass and the Al₂O₃ coating that has a higher melting temperature than the Al₂O₃. Therefore, when the Al₂O₃ is annealed, the glass is protected by this buffer layer which can be, for example, MgO. The laser used for annealing for example, has a wavelength that is not absorbed in the Al₂O₃ that would otherwise be absorbed by the glass substrate if it were not for the buffer layer. In one embodiment of the invention the MgO buffer layer is textured (has preferential orientation). This means that the Al₂O₃ when annealed will take on the underlying MgO texture. Besides Al₂O₃ ceramic, other ceramics such as zirconium nitride (ZrN) or titanium nitride (TiN) can be used. High texture in these ceramics is known to be highly advantageous as many materials show improved electronic properties when there is texture—and a textured sapphire substrate would allow for deposition of high quality textured films of many semiconductor materials such as GaN for LEDs, or OLEDs. Moreover, having a buffer layer between the glass and the Al₂O₃ provides room for error which may be necessary even when a carbon dioxide laser is used with a wavelength that will not damage or melt the underlying glass. The melting point of MgO is 2,852° C. whereas the melting point of Al₂O₃ is 2072° C. The crystallization temperature of amorphous Al₂O₃ by laser or e-beam varies depending on desired crystallinity, but typically it starts at around 600° C. and goes up to around 1300° C. maximum. These temperatures are well below the melting point of MgO but higher than glass. The melting point of glass, for example ordinary soda-lime glass, is between 550° C.-600° C. Different temperature ranges will result in a particular phase of Al₂O₃ with distinct properties. For example, gamma phase Al₂O₃ is achievable around 800° C., while the alpha phase is typically achievable around 1000° C. Such temperature ranges include 550° C. to 600° C., 600° C. to 800° C., 800° C. to 1000° C., 1000° C. to 1200° C. In the present invention, various textures (crystal orientations) can be used, but [111] is preferable. In the present invention, the grains of both the MgO and Al₂O₃ coating can be large, though it may be desirable to have smaller grain sizes. Besides Al₂O₃, other transparent ceramics such as Aluminum Oxynitride (AlON) or magnesium aluminate spinel (MgAl₂O₄) could be used. MgO doping of Al₂O₃ helps with density and therefore porosity.

The ceramic glass in an embodiment of the present invention can be used for a variety of applications such as covers to solar panels, displays, automobile windows, and substrates for LEDs. It can also be used for the cover glass used in CICs in solar panels for satellites. A CIC is an assembly usually comprised of a solar cell+interconnects+cover glass+bypass Diode. The cover glass (in some cases around 75 microns) protects the cell from cosmic radiation, i.e. electron and proton radiation. Sapphire is a particularly effective material for this protective purpose. And in one embodiment of the present invention, the sapphire glass is composed of ultra-thin layers which reduce the cost of manufacturing CICs.

The conducting layers in the present invention can be used for touch screens requiring a conductive layer. Moreover, the films in the present invention may have anti-reflective and hydrophobic or oleophobic properties useful in display glass.

### EXAMPLE 5

Following patent application US 2014/024,5947 by Vispute et al, MgO is deposited on soda-lime glass with high texture. Following patent application US 2015/026,7289 by Chaudhari and Vispute, Al₂O₃ and/or other ceramic materials are deposited on the MgO/glass substrate. Then, rather than annealing by heating the substrate, a laser or heated line source is applied to the Al₂O₃. The laser can be one of any number of lasers with various wavelengths used in the art, including a near field optical laser. For example, gas lasers, solid-state lasers, dye lasers, semiconductor laser, can be used, along with UV, visible, IR wavelengths. A pulsed laser can be used. Various spot sizes of the laser can also be used. Since the thickness of the MgO (or other suitable transparent buffer layer with a higher melting temperature than Al₂O₃) layer is greater than the Al₂O₃ film it allows for some room or margin of error should the laser beam pass through the Al₂O₃ layer. In this case, the laser will hit the MgO buffer layer but will not melt it. The MgO thickness here is 7 microns, but could be much less. For example, the MgO layer could be 1 micron or less. The Al₂O₃ thickness here is 2-3 microns, but could be more or less.

For example, the Al₂O₃ thickness could be equal to or less than 100 nm. Very thin films can have many advantages when making devices, such as reducing strain in any layers which are deposited on top. Since the MgO layer is almost 100% transparent, there is no noticeable effect on the quality of transparency in the device. Moreover, the MgO buffer layer allows for transparent substrates with even lower melting temperatures than soda-lime glass. For example, transparent plastic can be used on which MgO is then deposited with or without texture. The phase of Al₂O₃ in this invention is preferably alpha, as this phase is known for its hardness, but could also be gamma—which has certain other advantageous properties such as no bi-refringence which causes light scattering—or other phases if a lower temperature laser annealing process is desirable.

In the present invention, the terms ‘textured’ and ‘large grain’ have the following meaning: ‘textured’ means that the crystals in the film have preferential orientation either out-of-plane or in-plane or both. For example, in the present invention the films could be highly oriented out-of-plane, along the c-axis. By ‘large grained’ it is meant that the grain size is greater than or equal to the film thickness.

While the present invention has been described in conjunction with specific embodiments, those of normal skill in the art will appreciate the modifications and variations can be made without departing from the scope and the spirit of the present invention. Such modifications and variations are envisioned to be within the scope of the appended claims.

1. A method of making a ceramic coated substrate comprising the steps of:
depositing a textured transparent buffer layer on a transparent substrate,
depositing an amorphous ceramic layer on the textured transparent buffer layer, and
annealing the ceramic layer with a heated line source, said ceramic layer crystallizing forming a ceramic coated substrate.

2. The method of claim 1 where the substrate is glass.

3. The method of claim 1, where the substrate is ceramic.

4. The method of claim 1, where the substrate is plastic (polymer).

5. The method of claim 1, where the heated line source is a laser.

6. The method of claim 1, where the ceramic is Al₂O₃.

7. The method of claim 1, where the transparent buffer layer is MgO.

8. The method of claim 1, where the phase of Al₂O₃ is alpha.

9. The method of claim 1, where the MgO is textured.

10. A method of making a ceramic coated substrate without thermally impacting the substrate comprising the steps of:
depositing a textured transparent buffer layer on a transparent substrate,
depositing an amorphous ceramic layer on the textured transparent buffer layer, and
annealing the ceramic layer with a heated line source, said ceramic layer crystallizing forming a ceramic coated substrate, wherein the annealing takes place without thermally impacting the substrate.

11. The method of claim 10, wherein said buffer layer is MgO.

12. The method of claim 10, wherein said transparent substrate is glass.

13. The method of claim 10, wherein said ceramic is Al₂O₃.

14. The method of claim 10, wherein said ceramic has a thickness of less than 100 nm.

15. The method of claim 10, wherein said buffer layer has a thickness of less than 1 micron.

16. The method of claim 1, wherein said ceramic coated substrate is used in the covers of solar panels.

17. The method of claim 1, wherein said sapphire coated glass is used in CICs.

18. The method of claim 1, wherein said ceramic coated substrate is used in displays.

19. The method of claim 10, wherein the ceramic coated substrate is used as a substrate for LEDs or OLEDs.

20. The method of claim 1, wherein the thickness of the ceramic film is less than 100 nm.

21. A ceramic glass assembly comprising:
a textured transparent buffer layer on a transparent substrate, and an amorphous film deposited on said textured buffer layer.

22. The ceramic glass assembly of claim 20, wherein said amorphous film is heated by a laser and thereby crystallized.

23. The ceramic glass assembly if claim 20, wherein said amorphous film is heated by an electron beam evaporator and thereby crystallized.
